(19) United States
(12) Patent Application Publication
(10) Pub. No.: US 2004/0251539 A1
(43) Pub. Date: Dec. 16, 2004

(54) Thermoelectric cooler array

(76) Inventors: Sadeg M. Faris, Pleasantville, NY (US); Jaujeng Lin, Yorktown Heights, NY (US)

Correspondence Address: REVEO, INC., 3 WESTCHESTER PLAZA, ELMSFORD, NY, 10523, US

(21) Appl. No.: 10/801,065

(22) Filed: Mar. 15, 2004

Related U.S. Application Data
(63) Continuation-in-part of application No. 09/950,909, filed on Sep. 12, 2001.

(51) Int. Cl. H01L 35/34

(52) U.S. Cl. 257/712

(57) ABSTRACT

A novel thermoelectric cooler array and method of making the same are disclosed. The thermoelectric cooler array is a multistage thermoelectric cooler which provides a cascaded configuration for providing heat transfer from a cold sink to a heat sink. The multistage configuration provides for much higher heat transfer range and further provides benefit of thermoelectric cooling integrated with active electronic or optoelectronic components. The method of manufacturing the thermoelectric cooling array provides for n-type and p-type thermoelectric material substrates to be selectively bonded and sliced to create the desired stages of the multistage thermoelectric cooler.

### CROSS-REFERENCE TO RELATED APPLICATIONS

The present application is a continuation-in-part of and claims the benefit under 35 U.S.C. §120 of copending U.S. patent application Ser. No. 09/950,909 filed on Sep. 12, 2001 entitled “Thin Films and Production Methods Thereof,” which is herein incorporated by reference.

### TECHNICAL FIELD

The present invention relates generally to thermoelectric coolers, and more particularly, to a thermoelectric cooler array for microelectronic and optoelectronic components.

### BACKGROUND ART

Microelectronic and optoelectronic devices, as well as most integrated circuit devices, operate faster at sub-ambient temperatures. For example; the performance of an integrated circuit device typically improves by approximately 50% when the operating temperature is −50° C. instead of ambient room temperature. Similar scale improvements in performance can be seen in interconnects between components on the integrated circuit device. Therefore, microelectronic and optoelectronic devices, and almost every other integrated circuit device can benefit significantly in performance when cooled to sub-ambient temperatures.

Thermoelectric cooling systems are analogous to conventional refrigeration cooling systems. For example, a conventional cooling system includes an evaporator, a compressor, and a condenser. In the evaporator or cold section, pressurized refrigerant is allowed to expand, boil, and evaporate. During the change of state from a liquid to a gas, energy in the form of heat is absorbed. In the next step, the compressor re-compresses the gas into a liquid. Further, the condenser expels the heat absorbed at the evaporator and the extra heat added by the compressor to the ambient environment.

A thermoelectric cooling system has similar subassemblies. Efficient and cost-effective thermoelectric cooling is especially useful for improving the stability, resolution and speed in a variety of applications. Powerful and compact thermoelectric cooling can improve the performance of microprocessors, infrared detector, laser diodes, charge coupled devices, and the like. Portable refrigeration, thermal cyclers, and other temperature management tools are also available.

Thermoelectric cooling is the abstraction of heat from electronic components by Peltier effect, made possible with the use of certain solid-state thermoelectric materials such as lead telluride (PbTe) or bismuth telluride (Bi₂Te₃). The Peltier effect is a phenomenon whereby heat is liberated or absorbed at a junction when current passes from one metal to another. In this application, a cold junction (the place where the heat source or load is located) is defined as the assembly where energy in the form of heat is absorbed when current passes from one metal to another. A hot junction (the place where the heat sink is located) is the assembly which thermally communicates with a heat exchanger and through which the heat that is liberated, when current passes from one metal to another, is transferred to the ambient environment. Devices using this effect, e.g. frigistors, are used for automatic temperature control, and the like and are energized by direct current (“DC”) thermoelectric materials, that is, any set of materials (metals) which constitute a thermoelectric system.

However, there is a performance limit for thermoelectric materials. A one-stage thermoelectric cooler can provide, at most, approximately 70° K maximum temperature difference, if one end remains at ambient temperature. Multistage (or cascaded) thermoelectric coolers can be used to obtain larger temperature differences. However, the size and cost of multistage thermoelectric cooling has been prohibitive for all but the most demanding applications.

Therefore, there is a need for a cost-effective multistage thermoelectric cooling system which can build upon the one-stage thermoelectric cooling devices using the Peltier effect.

### SUMMARY OF THE INVENTION

The above-discussed and other problems and deficiencies of the prior art are overcome or alleviated, and the objects of the invention are attained, by the several methods and apparatus of the present invention.

In one aspect, the invention is a thermoelectric cooler comprising: a multistage thermoelectric cooler, each stage of said multistage cooler arranged with a Peltier device interposed between an intermediate heat sink and an intermediate cold sink, said Peltier device configured to exhibit a voltage drop.

In another aspect, the invention is a method of manufacturing a multistage thermoelectric cooler, said method comprising the steps of: creating an n-type thermoelectric substrate; creating a p-type thermoelectric substrate; selectively bonding said n-type thermoelectric substrate with said p-type thermoelectric substrate horizontally; and slicing vertically said bonded substrate.

### BRIEF DESCRIPTION OF THE DRAWINGS

The foregoing summary as well as the following detailed description of preferred embodiments of the invention, will be better understood when read in conjunction with the appended drawings. For the purpose of illustrating the invention, there is shown in the drawings embodiments which are presently preferred. It should be understood, however, that the invention is not limited to the precise arrangements and instrumentalities shown. In the drawings, wherein:

FIG. 1 is a schematic cross-section diagram of a selectively bonded multi layer substrate in accordance with the principles of the invention;

FIG. 2 is a schematic cross-section diagram of a selectively bonded multi layer substrate in accordance with the principles of the invention;

FIG. 3 is a schematic cross-section diagram of a selectively bonded multi layer substrate in accordance with the principles of the invention;

FIG. 4 is a schematic cross-section diagram of a selectively bonded multi layer substrate in accordance with the principles of the invention;

FIG. 5 is a schematic cross-section diagram of a selectively bonded multi layer substrate in accordance with the principles of the invention;

FIG. 6 is a schematic cross-section diagram of a selectively bonded multi layer substrate in accordance with the principles of the invention;

FIG. 7 is a schematic cross-section diagram of a selectively bonded multi layer substrate in accordance with the principles of the invention;

FIG. 8 is a schematic cross-section diagram of a selectively bonded multi layer substrate in accordance with the principles of the invention;

FIG. 9 is a schematic cross-section diagram of a selectively bonded multi layer substrate in accordance with the principles of the invention;

FIG. 10 is a schematic cross-section diagram of a selectively bonded multi layer substrate in accordance with the principles of the invention;

FIG. 11 is a schematic cross-section diagram of a selectively bonded multi layer substrate in accordance with the principles of the invention;

FIG. 12 is a schematic cross-section diagram of a selectively bonded multi layer substrate in accordance with the principles of the invention;

FIG. 13 is a schematic cross-section diagram of a selectively bonded multi layer substrate in accordance with the principles of the invention;

FIG. 14 is a schematic process diagram of the MFT process;

FIG. 15 is a schematic diagram illustrating ion implantation for the cleavage force for the MFT process;

FIG. 16 is a schematic process flow diagram for manufacturing a thermoelectric cooler array in accordance with the principles of the invention;

FIG. 17 is a schematic diagram of a prior art implementation of a thermoelectric cooler;

FIG. 18 is a schematic diagram of a single multistage thermoelectric cooler in accordance with the principles of the invention; and

FIG. 19 is an isometric schematic diagram of a single thermoelectric cooling array in accordance with the principles of the invention.

### DETAILED DESCRIPTION OF THE DRAWINGS

The disclosed thermoelectric cooling system disclosed in the invention can improve the cooling capability of the known thermoelectric microcoolers by dramatically increasing the number of thermoelectric couplers in a small volume. A good thermoelectric material must exhibit a combination of properties that do not exist in conventional metals. Desirable thermoelectric materials must exhibit a combination of high electrical conductivity of metals and the low thermal conductivity as in insulators. A combination of these characteristics is measured by the thermoelectric figure of merit ZT. The typical ZT figure for the best bulk materials is about 1.

Thermoelectric coolers made from commercially available thermoelectric materials provide, at most, approximately 70° K maximum temperature difference when the hot end remains at ambient temperature. To obtain better performance (larger temperature differences), the thermocoolers must be arranged in multistage (or cascaded) configuration to advantageously utilize multiple thermoelectric couplers.

Temperature control for microelectronic and optoelectronic components is typically accomplished with thermoelectric (TE) coolers. TE coolers have become essential in modern optical telecommunications to control the characteristics of laser sources, switching/routing elements, and detectors used in wavelength division multiplexed systems. Cooling requirements in microprocessors and other integrated circuits have also risen dramatically in recent years due to the increase in clock speed and reduction in feature size. Generally, as these devices have become denser, smaller, and faster, the power density has greatly increased. Conventional TE coolers are incompatible with integrated circuit fabrication processes, and are therefore limited in how compact they can be manufactured. Thus, current bulk TE fabrication processes leads to high packaging costs during integration with microelectronic and optoelectronic devices. Furthermore, the reliability of packaged modules employing a TE cooler is usually limited by the reliability of the cooler itself. Therefore, the development of thermal control for instruments has shifted from bulk thermoelements to integrated thin film coolers.

The greatest advantage of thin film coolers is the dramatic gain in cooling power density, as it is inversely proportional to the length of the thermoelements. Thin films on the order of microns should provide cooling power densities greater than 1000 W/cm². Several additional methods have also been explored for thermoelectric cooling such as thermionic emission in heterostructures and decreased thermal conductivity in superlattice structures. Thin film coolers are also advantageous since they can be manufactured in large quantities using well known integrated circuit fabrication techniques.

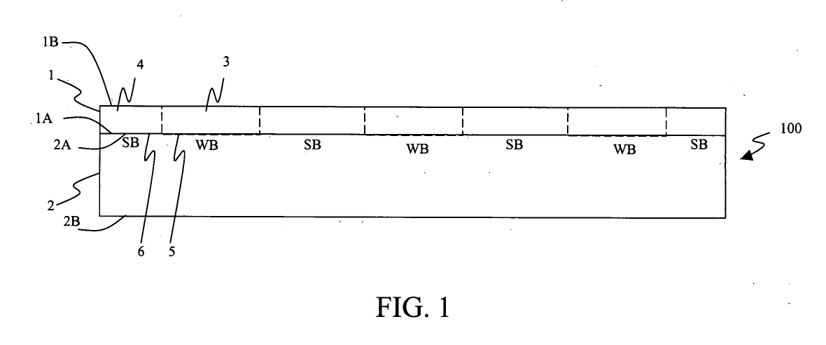

As mentioned previously, a lot of effort has been committed to improving the figure of merit ZT. Currently, the best thin film superlattice thermoelectric devices are reported to demonstrate ZT˜2.4 at 300 K. Even in power conversion mode, this kind of device can only provide a temperature difference of around 70 K. Multistage thermoelectric devices is capable of providing much larger temperature difference between hot end and cold end, but currently, the fabrication process of multistage thermoelectric devices is too bulky (a few millimeters) for thin film process integration (FIG. 1), and consumes a significant amount of expensive thermoelectric materials if the number of thermoelectric elements is significantly increased.

To enable this multistaging of thermoelectric materials, an enabling technology is necessary for combining various thermoelectric materials in a compact size while retaining performance. A cost-effective manner of combining the thermoelectric materials while maintaining compact volume in a cost effective manner is massive filo-layer technology (“MFT”).

By being able to peel off and transfer thin semiconductor layer without wasting any materials, thermoelectric elements in each stage of a multistage thermoelectric cooling device could be produced in a very economical, compact and dense fashion. Each stage becomes so thin that it allows more flexible modularization designs for multistage configuration. The significantly reduced thickness of the overall multistage structure also enable integration with microelectronic and optoelectronic devices. This UDMTM (Ultra-Dense Multistage Thermoelectric Micro-cooler) now contains a huge number of thermoelectric elements to provide much larger temperature difference between the hot and cold end while still occupying only a small amount of space. Compared to current technology, the MFT approach enjoys numerous advantages:

Prior to discussion of specific formation of these three-dimensional integrated circuits, a discussion of the starting substrates is presented, as set forth in Applicant's copending U.S. patent application Ser. No. 09/950,909 filed on Sep. 12, 2001 entitled “Thin films and Production Methods Thereof.” This substrate, referred to as a selectively bonded multiple layer substrate, allows for processing of multiple chips on a wafer as is known, but allows the chip layer of the wafer to be readily removed, preferably without mechanical grinding or other etch-back techniques. This chip layer then may be stacked on another chip layer, as described hereinafter, or alternatively, the chip layer may be diced into individual chips and stacked.

Referring to FIG. 1, a selectively bonded multiple layer substrate 100 is shown. The multiple layer substrate 100 includes a layer 1 having an exposed surface 1B, and a surface 1A selectively bonded to a surface 2A of a layer 2. Layer 2 further includes an opposing surface 2B. In general, to form the selectively bonded multiple layer substrate 100, layer 1, layer 2, or both layers 1 and 2 are treated to define regions of weak bonding 5 and strong bonding 6, and subsequently bonded, wherein the regions of weak bonding 5 are in a condition to allow processing of a useful device or structure.

Generally, layers 1 and 2 are compatible. That is, the layers 1 and 2 constitute compatible thermal, mechanical, and/or crystalline properties. In certain preferred embodiments, layers 1 and 2 are the same materials. Of course, different materials may be employed, but preferably selected for compatibility.

One or more regions of layer 1 are defined to serve as the substrate region within or upon which one or more structures, such as microelectronics may be formed. These regions may be of any desired pattern, as described further herein. The selected regions of layer 1 may then be treated to minimize bonding, forming the weak bond regions 5. Alternatively, corresponding regions of layer 2 may be treated (in conjunction with treatment of layer 1, or instead of treatment to layer 1) to minimize bonding. Further alternatives include treating layer 1 and/or layer 2 in regions other than those selected to form the structures, so as to enhance the bond strength at the strong bond regions 6.

After treatment of layer 1 and/or layer 2, the layers may be aligned and bonded. The bonding may be by any suitable method, as described further herein. Additionally, the alignment of the layers may be mechanical, optical, or a combination thereof. It should be understood that the alignment at this stage may not, be critical, insomuch as there are generally no structures formed on layer 1. However, if both layers 1 and 2 are treated, alignment may be required to minimize variation from the selected substrate regions.

The multiple layer substrate 100 may be provided to a user for processing of any desired structure in or upon layer 1. Accordingly, the multiple layer substrate 100 is formed such that the user may process any structure or device using conventional fabrication techniques, or other techniques that become known as the various related technologies develop. Certain fabrication techniques subject the substrate to extreme conditions, such as high temperatures, pressures, harsh chemicals, or a combination thereof. Thus, the multiple layer substrate 100 is preferably formed so as to withstand these conditions.

Useful structures or devices may be formed in or upon regions 3, which partially or substantially overlap weak bond regions 5. Accordingly, regions 4, which partially or substantially overlap strong bond regions 6, generally do not have structures therein or thereon. After a user has formed useful devices within or upon layer 1 of the multiple layer substrate 100, layer 1 may subsequently be debonded. The debonding may be by any known technique, such as peeling, without the need to directly subject the useful devices to detrimental delamination techniques. Since useful devices are not generally formed in or on regions 4, these regions may be subjected to debonding processing, such as ion implantation, without detriment to the structures formed in or on regions 3.

To form weak bond regions 5, surfaces 1A, 2A, or both may be treated at the locale of weak bond regions 5 to form substantially no bonding or weak bonding. Alternatively, the weak bond regions 5 may be left untreated, whereby the strong bond region 6 is treated to induce strong bonding. Region 4 partially or substantially overlaps strong bond region 6. To form strong bond region 4, surfaces 1A, 2A, or both may be treated at the locale of strong bond region 6. Alternatively, the strong bond region 6 may be left untreated, whereby the weak bond region 5 is treated to induce weak bonding. Further, both regions 5 and 6 may be treated by different treatment techniques, wherein the treatments may differ qualitatively or quantitatively. After treatment of one or both of the groups of weak bond regions 5 and strong bond regions 6, layers 1 and 2 are bonded together to form a substantially integral multiple layer substrate 100. Thus, as formed, multiple layer substrate 100 may be subjected to harsh environments by an end user, e.g., to form structures or devices therein or thereon, particularly in or on regions 3 of layer 1.

For purposes of this specification, the phrase “weak bonding” or “weak bond” generally refers to a bond between layers or portions of layers that may be readily overcome, for example by debonding techniques such as peeling, other mechanical separation, heat, light, pressure, or combinations comprising at least one of the foregoing debonding techniques. These debonding techniques minimally defect or detriment the layers 1 and 2, particularly in the vicinity of weak bond regions 5.

The treatment of one or both of the groups of weak bond regions 5 and strong bond regions 6 may be effectuated by a variety of methods. The important aspect of the treatment is that weak bond regions 5 are more readily debonded (in a subsequent debonding step as described further herein) than the strong bond regions 6. This minimizes or prevents damage to the regions 3, which may include useful structures thereon, during debonding. Further, the inclusion of strong bond regions 6 enhances mechanical integrity of the multiple layer substrate 100 especially during structure processing. Accordingly, subsequent processing of the layer 1, when removed with useful structures therein or thereon, is minimized or eliminated.

The ratio of the bond strengths of the strong bond regions to the weak bond regions (SB/WB) in general is greater than 1. Depending on the particular configuration of the strong bond regions and the weak bond regions, and the relative area sizes of the strong bond regions and the weak bond regions, the value of SB/WB may approach infinity. That is, if the strong bond areas are sufficient in size and strength to maintain mechanical and thermal stability during processing, the bond strength of the weak bond areas may approach zero. However, the ratio SB/WB may vary considerably, since strong bonds strengths (in typical silicon and silicon derivative, e.g., SiO2, wafers) may vary from about 500 millijoules per squared meter (mj/m2) to over 5000 mj/m2 as is taught in the art (see, e.g., Q. Y. Tong, U. Goesle, Semiconductor Wafer Bonding, Science and Technology, pp. 104-118, John Wiley and Sons, New York, N.Y. 1999, which is incorporated herein by reference). However, the weak bond strengths may vary even more considerably, depending on the materials, the intended useful structure (if known), the bonding and debonding techniques selected, the area of strong bonding compared to the area of weak bonding, the strong bond and weak bond configuration or pattern on the wafer, and the like. For example, where ion implantation is used as a step to debond the layers, a useful weak bond area bond strength may be comparable to the bond strength of the strong bond areas after ion implantation and/or related evolution of microbubbles at the implanted regions. Accordingly, the ratio of bond strengths SB/WB is generally greater than 1, and preferably greater than 2, 5, 10, or higher, depending on the selected debonding techniques and possibly the choice of the useful structures or devices to be formed in the weak bond regions.

The particular type of treatment of one or both of the groups of weak bond regions 5 and strong bond regions 6 undertaken generally depends on the materials selected. Further, the selection of the bonding technique of layers 1 and 2 may depend, at least in part, on the selected treatment methodology. Additionally, subsequent debonding may depend on factors such as the treatment technique, the bonding method, the materials, the type or existence of useful structures, or a combination comprising at least one of the foregoing factors. In certain embodiments, the selected combination of treatment, bonding, and subsequent debonding (i.e., which may be undertaken by an end user that forms useful structures in regions 3 or alternatively, as an intermediate component in a higher level device) obviates the need for cleavage propagation to debond layer 1 from layer 2 or mechanical thinning to remove layer 2, and preferably obviates both cleavage propagation and mechanical thinning. Accordingly, the underlying substrate may be reused with minimal or no processing, since cleavage propagation or mechanical thinning damages layer 2 according to conventional teachings, rendering it essentially useless without further substantial processing.

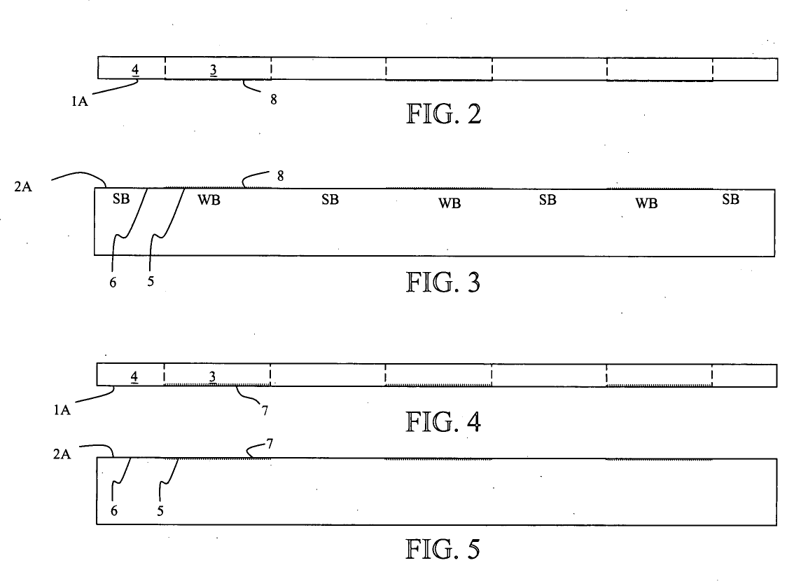

Referring to FIGS. 2 and 3, wherein similarly situated regions are referenced with like reference numerals, one treatment technique includes use of a slurry containing a solid component and a decomposable component on surface 1A, 2A, or both 1A and 2A. The solid component may be, for example, alumina, silicon oxide (SiO(x)), other solid metal or metal oxides, or other material that minimizes bonding of the layers 1 and 2. The decomposable component may be, for example, polyvinyl alcohol (PVA), or another suitable decomposable polymer. Generally, a slurry 8 is applied in weak bond region 5 at the surface 1A (FIG. 2), 2A (FIG. 3), or both 1A and 2A. Subsequently, layers 1 and/or 2 may be heated, preferably in an inert environment, to decompose the polymer. Accordingly, porous structures (comprised of the solid component of the slurry) remain at the weak bond regions 5, and upon bonding, layers 1 and 2 do not bond at the weak bond regions 5.

Referring to FIGS. 4 and 5, another treatment technique may rely on variation in surface roughness between the weak bond regions 5 and strong bond regions 6. The surface roughness may be modified at surface 1A (FIG. 4), surface 2A (FIG. 5), or both surfaces 1A and 2A. In general, the weak bond regions 5 have higher surface roughness 7 (FIGS. 4 and 5) than the strong bond regions 6. In semiconductor materials, for example the weak bond regions 5 may have a surface roughness greater than about 0.5 nanometer (nm), and the strong bond regions 4 may have a lower surface roughness, generally less than about 0.5 nm. In another example, the weak bond regions 5 may have a surface roughness greater than about 1 nm, and the strong bond regions 4 may have a lower surface roughness, generally less than about 1 nm. In a further example, the weak bond regions 5 may have a surface roughness greater than about 5 nm, and the strong bond regions 4 may have a lower surface roughness, generally less than about 5 nm. Surface roughness can be modified by etching (e.g., in KOH or HF solutions) or deposition processes (e.g., low pressure chemical vapor deposition (“LPCVD”) or plasma enhanced chemical vapor deposition (“PECVD”)). The bonding strength associated with surface roughness is more fully described in, for example, Gui et al., “Selective Wafer Bonding by Surface Roughness Control”, Journal of The Electrochemical Society, 148 (4) G225-G228 (2001), which is incorporated by reference herein.

In a similar manner (wherein similarly situated regions are referenced with similar reference numbers as in FIGS. 4 and 5), a porous region 7 may be formed at the weak bond regions 5, and the strong bond regions 6 may remain untreated. Thus, layer 1 minimally bonds to layer 2 at locale of the weak bond regions 5 due to the porous nature thereof. The porosity may be modified at surface 1A (FIG. 4), surface 2A (FIG. 5), or both surfaces 1A and 2A. In general, the weak bond regions 5 have higher porosities at the porous regions 7 (FIGS. 4 and 5) than the strong bond regions 6.

Another treatment technique may rely on selective etching of the weak bond regions 5 (at surfaces 1A (FIG. 4), 2A (FIG. 5), or both 1A and 2A), followed by deposition of a photoresist or other carbon containing material (e.g., including a polymeric based decomposable material) in the etched regions. Upon bonding of layers 1 and 2, which is preferably at a temperature sufficient to decompose the carrier material, the weak bond regions 5 include a porous carbon material therein, thus the bond between layers 1 and 2 at the weak bond regions 5 is very weak as compared to the bond between layers 1 and 2 at the strong bond region 6. One skilled in the art will recognize that depending on the circumstances, a decomposing material will be selected that will not out-gas, foul, or otherwise contaminate the substrate layers 1 or 2, or any useful structure to be formed in or upon regions 3.

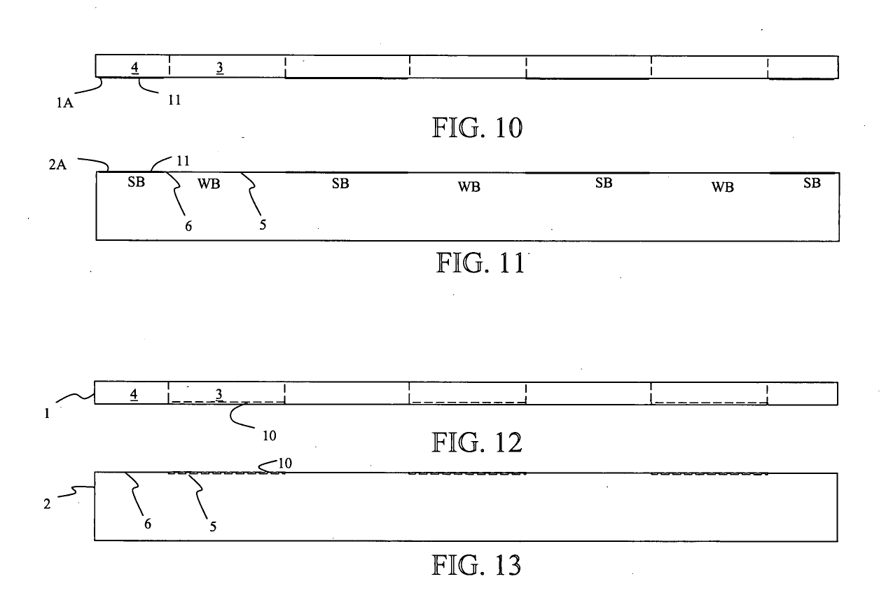

A further treatment technique may employ irradiation to attain strong bond regions 6 and/or weak bond regions 5. In this technique, layers 1 and/or 2 are irradiated with neutrons, ions, particle beams, or a combination thereof to achieve strong and/or weak bonding, as needed. For example, particles such as He+, H+, or other suitable ions or particles, electromagnetic energy, or laser beams may be irradiated at the strong bond regions 6 (at surfaces 1A (FIG. 10), 2A (FIG. 11), or both 1A and 2A). It should be understood that this method of irradiation differs from ion implantation for the purpose of delaminating a layer, generally in that the doses and/or implantation energies are much less (e.g., on the order of 1/100th to 1/1000th of the dosage used for delaminating).

Referring to FIGS. 8 and 9, a still further treatment technique involves etching the surface of the weak bond regions 5. During this etching step, pillars 9 are defined in the weak bond regions 5 on surfaces 1A (FIG. 8), 2A (FIG. 9), or both 1A and 2A. The pillars may be defined by selective etching, leaving the pillars behind. The shape of the pillars may be triangular, pyramid shaped, rectangular, hemispherical, or other suitable shape. Alternatively, the pillars may be grown or deposited in the etched region. Since there are less bonding sites for the material to bond, the overall bond strength at the weak bond region 5 is much weaker then the bonding at the strong bond regions 6.

Yet another treatment technique involves inclusion of a void area 10 (FIGS. 12 and 13), e.g., formed by etching, machining, or both (depending on the materials used) at the weak bond regions 5 in layer 1 (FIG. 12), 2 (FIG. 13). Accordingly, when the first layer 1 is bonded to the second layer 2, the void areas 10 will minimize the bonding, as compared to the strong bond regions 6, which will facilitate subsequent debonding.

Referring again to FIGS. 2 and 3, another treatment technique involves use of one or more metal regions 8 at the weak bond regions 5 of surface 1A (FIG. 2), 2A (FIG. 3), or both 1A and 2A. For example, metals including but not limited to Cu, Au, Pt, or any combination or alloy thereof may be deposited on the weak bond regions 5. Upon bonding of layers 1 and 2, the weak bond regions 5 will be weakly bonded. The strong bond regions may remain untreated (wherein the bond strength difference provides the requisite strong bond to weak bond ratio with respect to weak bond layers 5 and strong bond regions 6), or may be treated as described above or below to promote strong adhesion.

A further treatment technique involves use of one or more adhesion promoters 11 at the strong bond regions 6 on surfaces 1A (FIG. 10), 2A (FIG. 11), or both 1A and 2A. Suitable adhesion promoters include, but are not limited to, TiO(x), tantalum oxide, or other adhesion promoter. Alternatively, adhesion promoter may be used on substantially all of the surface 1A and/or 2A, wherein a metal material is be placed between the adhesion promoter and the surface 1A or 2A (depending on the locale of the adhesion promoter) at the weak bond regions 5. Upon bonding, therefore, the metal material will prevent strong bonding a the weak bond regions 5, whereas the adhesion promoter remaining at the strong bond regions 6 promotes strong bonding.

Yet another treatment technique involves providing varying regions of hydriphobicity and/or hydrophillicity. For example, hydrophilic regions are particularly useful for strong bond regions 6, since materials such as silicon may bond spontaneously at room temperature. Hydrophobic and hydrophilic bonding techniques are known, both at room temperature and at elevated temperatures, for example, as described in Q. Y. Tong, U. Goesle, Semiconductor Wafer Bonding, Science and Technology, pp. 49-135, John Wiley and Sons, New York, N.Y. 1999, which is incorporated by reference herein.

A still further treatment technique involves one or more exfoliation layers that are selectively irradiated. For example, one or more exfoliation layers may be placed on the surface 1A and/or 2A. Without irradiation, the exfoliation layer behaves as an adhesive. Upon exposure to irradiation, such as ultraviolet irradiation, in the weak bond regions 5, the adhesive characteristics are minimized. The useful structures may be formed in or upon the weak bond regions 5, and a subsequent ultraviolet irradiation step, or other debonding technique, may be used to separate the layers 1 and 2 at the strong bond regions 6.

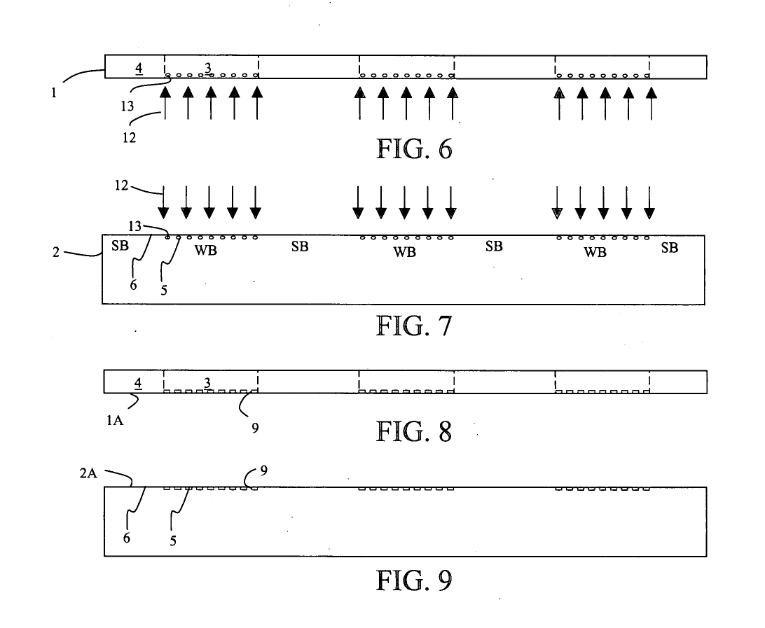

Referring to FIGS. 6 and 7, an additional treatment technique includes an implanting ions 12 (FIGS. 6 and 7) to allow formation of a plurality of microbubbles 13 in layer 1 (FIG. 6), layer 2 (FIG. 7), or both layers 1 and 2 in the weak regions 3, upon thermal treatment. Therefore, when layers 1 and 2 are bonded, the weak bond regions 5 will bond less than the strong bond regions 6, such that subsequent debonding of layers 1 and 2 at the weak bond regions 5 is facilitated.

Another treatment technique includes an ion implantation step followed by an etching step. In one embodiment, this technique is carried out with ion implantation through substantially all of the surface 1B. Subsequently, the weak bond regions 5 may be selectively etched. This method is described with reference to damage selective etching to remove defects in Simpson et al., “Implantation Induced Selective Chemical Etching of Indium Phosphide”, Electrochemical and Solid-State Letters, 4(3) G26-G27, which is herein incorporated by reference.

A still further treatment technique realizes one or more layers selectively positioned at weak bond regions 5 and/or strong bond regions 6 having radiation absorbing and/or reflective characteristics, which may be based on narrow or broad wavelength ranges. For example, one or more layers selectively positioned at strong bond regions 6 may have adhesive characteristics upon exposure to certain radiation wavelengths, such that the layer absorbs the radiation and bonds layers 1 and 2 at strong bond regions 6.

One of skill in the art will recognize that additional treatment technique may be employed, as well as combination comprising at least one of the foregoing treatment techniques. The key feature of any treatment employed, however, is the ability to form one or more region of weak bonding and one or more regions of strong bonding, providing SB/WB bond strength ratio greater than 1.

Multi-layer devices can be fabricated on a selectively bonded multiple layer substrate is shown. The multiple layer substrate includes a layer having an exposed surface, and a surface selectively bonded to a surface of a layer. The layer further includes an opposing surface. In general, to form the selectively bonded multiple layer substrate, the first layer, second layer, or both layers are treated to define regions of weak bonding and strong bonding, and subsequently bonded, wherein the regions of weak bonding are in a condition to allow processing of a useful device or structure.

Generally, the two layers are compatible. That is, the layers constitute compatible thermal, mechanical, and/or crystalline properties. In certain preferred embodiments, layers are the same materials. Of course, different materials may be employed, but preferably selected for compatibility.

One or more regions of layer are defined to serve as the substrate region within or upon which one or more structures, such as microelectronics may be formed. These regions may be of any desired pattern, as described further herein. The selected regions of layer may then be treated to minimize bonding, forming the weak bond regions. Alternatively, corresponding regions of the second layer may be treated (in conjunction with treatment of the first layer, or instead of treatment to the first layer) to minimize bonding. Further alternatives include treating the first and/or the second layer in regions other than those selected to form the structures, so as to enhance the bond strength at the strong bond regions.

After treatment of the first layer and/or the second layer, the layers may be aligned and bonded. The bonding may be by any suitable method, as described further herein. Additionally, the alignment of the layers may be mechanical, optical, or a combination thereof. It should be understood that the alignment at this stage may not, be critical, insomuch as there are generally no structures formed on the layer. However, if both layers are treated, alignment may be required to minimize variation from the selected substrate regions.

The multiple layer substrate may be provided to a user for processing of any desired structure in or upon the first layer. Accordingly, the multiple layer substrate is formed such that the user may process any structure or device using conventional fabrication techniques, or other techniques that become known as the various related technologies develop. Certain fabrication techniques subject the substrate to extreme conditions, such as high temperatures, pressures, harsh chemicals, or a combination thereof. Thus, the multiple layer substrate is preferably formed so as to withstand these conditions.

Useful structures or devices may be formed in or upon regions of the substrate, which partially or substantially overlap weak bond regions. Accordingly, other regions may partially or substantially overlap strong bond regions and generally do not have structures therein or thereon. After a user has formed useful devices within or upon the first layer of the multiple layer substrate, the first layer may subsequently be debonded. The debonding may be by any known technique, such as peeling, without the need to directly subject the useful devices to detrimental delamination techniques. Since useful devices are not generally formed in or on weak bond regions, these regions may be subjected to debonding processing, such as ion implantation, without detriment to the structures formed in or on regions.

To form weak bond regions, surfaces of the multiple layer substrate may be treated at the locale of weak bond regions to form substantially no bonding or weak bonding. After treatment of one or both of the groups of weak bond regions and strong bond regions, the first two layers are bonded together to form a substantially integral multiple layer substrate. Thus, as formed, multiple layer substrate may be subjected to harsh environments by an end user, e.g., to form structures or devices therein or thereon, particularly in or on weak bond regions of the first layer.

Recent parallel developments in bonding and thinning of silicon wafers have created a new, enabling technology for the transfer of thin layers. Wafer bonding takes advantage of a surface that is very smooth, very flat and very clean and therefore can form Van der Waals bonds when placed into intimate contact, and that these bonds can be converted to strong, atomic bonds with annealing. This method of forming a bond without adhesive is generally known as fusion bonding. The surfaces of single crystal silicon wafers are nearly atomically smooth and hence are ideal for fusion bonding. It is now routine to bond semiconductor wafers to each other with a bond strength that equals the bulk mechanical properties, and commercial, automated cluster tools are available to prepare and bond wafer pairs. However, up until recently, if it was desired to bond a thin layer onto a wafer, as is done in some silicon-on-insulator (“SOI”) manufacturing, the bulk of one of the bonded wafers had to be etched or mechanically polished away. This was a slow, expensive and tedious process.

A significant advance in thinning technology came with the announcement of the “Smart-Cut” process revealed in U.S. Pat. No. 5,374,564 to Bruel. Rather than grinding or etching the excess silicon, Bruel implanted hydrogen into a plane inside the wafer before bonding to create a plane of microcavities. After bonding the implanted wafer to an oxidized handle wafer, cleavage is propagated along the implant plane by applying heat or mechanical force. The cleavage generates an SOI wafer by splitting away the bulk of the implanted wafer, leaving a thin layer of single crystal silicon bonded to the oxidized handle wafer. The remainder of the wafer, which has been split off, is then re-used as the handle wafer for the next SOI wafer. The cleavage surface is remarkably smooth. To create an implant plane incised the silicon wafer, typical implant conditions for hydrogen are a dose of 5×1016 cm-2 and energy of 120 keV. For the above conditions, about 1 micron layer thickness can be cleaved from the wafer. The layer thickness is a function of the implant depth only, which for hydrogen in silicon is 90 Å/keV of implant energy.

The implantation of high energy particles heats the target significantly. Blistering must be avoided when implanting hydrogen by reducing beam currents by a factor of ½ or more, or by clamping and cooling the wafer. Splitting with lower hydrogen implant doses has been achieved with co-implantation of helium or boron (Smarter-Cut process). xv While this new, enabling technology has been commercialized to manufacture SOI wafers, there remain vast opportunities in 3-dimensional integration of microelectronics, in machining microelectromechanical devices, in optical devices and more.

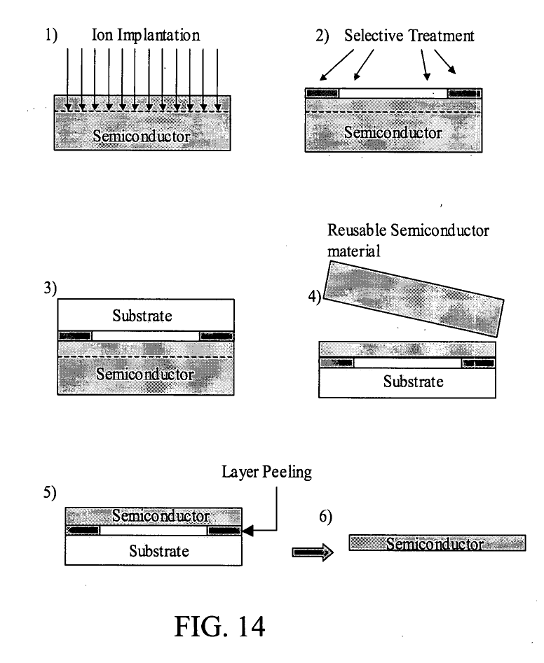

Referring to FIG. 14, a summary of the principles of the MFT process are shown. In step (1), the depth of ion implantation determines the thickness of the desired thin film. In steps (2) and (3), the selectively bonded structure is established between the silicon and the substrate layers. In steps (4) and (5), a primary peel-off process produces an ultra-thin layer selectively bonded to the supporting substrate. This thin layer is the MFT wafer. After a high temperature annealing process for repairing the surface damage caused by ion bombardment, the result is a MFT thin layer in step (6).

The layer peeling in step (5) may be accomplished by cleavage, either by mechanical force, chemical etching or ion implantation in the strong bond region. As stated previously, one method of selective treatment of the wafer substrate is to create a strong bond peripheral region and a weak bond central region on the wafer.

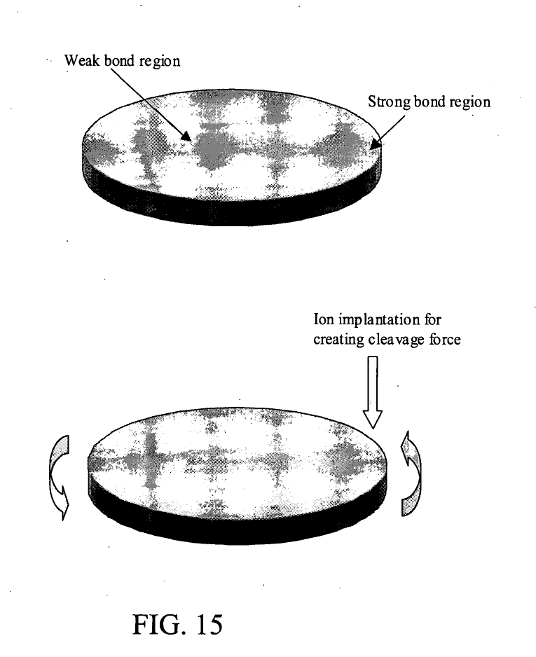

In a preferred embodiment, referring to FIG. 15, there is shown how ion implantation will be the method in creating this crucial cleavage force because it can be applied to a rotating wafer to improve the uniformity and stability of this process. Other approaches include chemically etching away the ultra thin layer above the strong bond region such that the rest of the ultra thin layer will be easy to peel off.

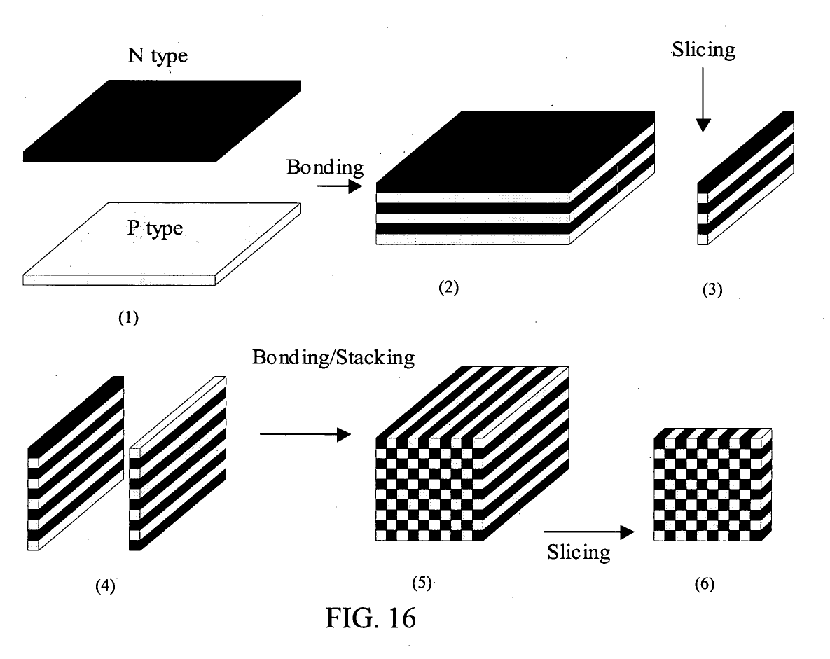

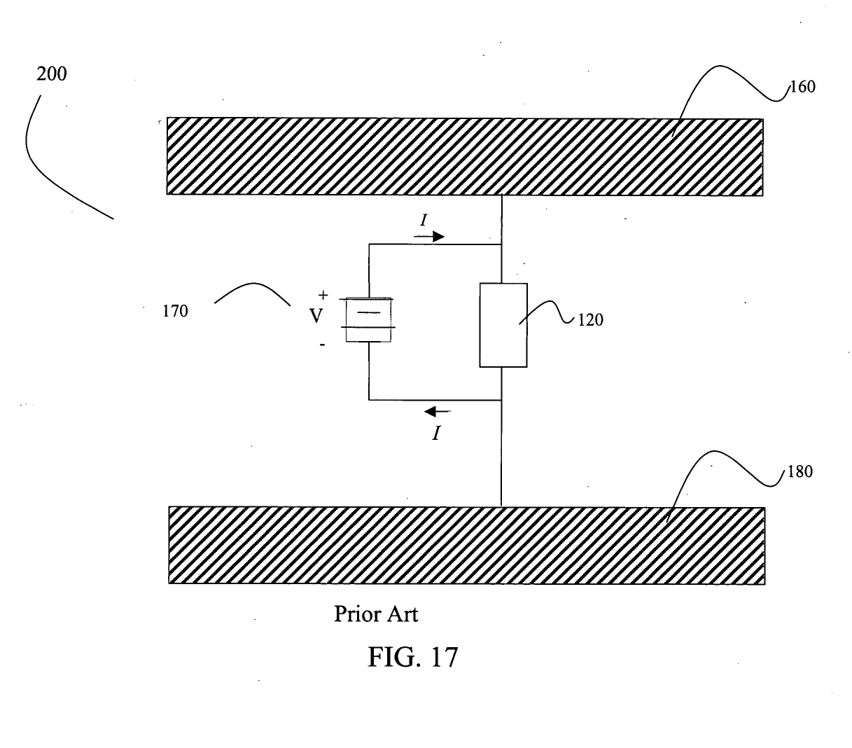

Referring now to FIG. 16, there is shown a process flow diagram for building n-type and p-type thermoelectric layers to be bonded together to form thermoelectric cooling arrays. In step (1), separate n-type and p-type thermoelectric layers are formed. In step (2), a plurality of the thermoelectric layers formed are bonded (or stacked) together. In step (3), the resultant structure is sliced vertically to produce a layer of synthetic thermoelectric arrays.

As a result of the MFT process, both the n-type and p-type wafers can be made very thin (on the order of approximately 10 μm). The thin wafers allows for many more thermoelectric coolers to be included in the resultant structure.

In a preferred embodiment, the resultant structure is bonded (or stacked) again in step (4). In steps (5) and (6), a checkerboard style thermoelectric coupling array is achieved when the resultant structure is sliced again.

The resulting thermoelectric coupling array is on the order of 10 times thinner than the thinnest thermoelectric thin film currently available. Accordingly, when the resultant structure is used to construct multistage microcoolers, within the same volume, one can fit in at least 10 times more layers of thermoelectric materials. Additionally, the fabrication process can be integrated into existing integrated circuit fabrication processes. Furthermore, expensive thermoelectric material is fully utilized when the bonding, stacking and slicing processes are completed.

Referring now to FIG. 17, there is shown a schematic diagram of a prior art implementation of a thermoelectric cooler 200 employing a Peltier device. The Peltier device 120 is typically fabricated from a thermoelectric material. In contrast to most metals that typically exhibit both high electrical and high thermal conductivity, Peltier materials exhibit very high electrical conductivity and relatively low thermal conductivity. As shown, Peltier device 120 is connected to a DC power supply 170 that provides an electric field V and a current I across Peltier device 120. During operation, the Peltier device 170 transports electrons from a cold sink 180 to a hot sink 160, in response to the electric field placed across Peltier device 120. The desired heat transfer is from cold sink 180 at temperature T_{cold} to hot sink 160 at temperature Tₕₒₜ.

It will be understood that thermoelectric cooler 200 can be incorporated within a semiconductor substrate or MFT wafer on which active electronic circuitry can be incorporated. First, active electronic circuitry is constructed on a wafer according to a specified design. The electronic circuitry can be constructed on the wafer by a set of standard fabrication steps as they are well-known in the art, up to a contact level. A protective surface, such as a thick photoresist film, is then put on top of the electric circuitry to provide mechanical protection for the electric circuitry. At this point, the wafer should resemble wafer FIG. 15.

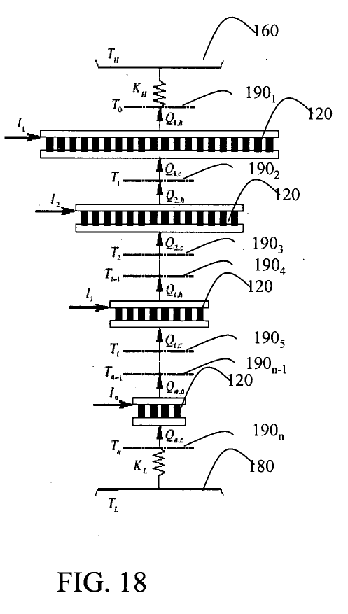

Referring now to FIG. 18, there is shown a schematic diagram of the cascaded thermoelectric cooler of the present invention. Each layer is constructed of a cold sink 180 and a heat sink 160 (represented as 190ₙ in the intermediate levels of the thermoelectric cooler). A Peltier device 120 at each level transports electrons (Q_{1,n}) from an intermediate sink 190ₙ₋₁ to another intermediate sink 190ₙ. Each intermediate sink 190ₙ represents a cold sink and a heat sink for the immediate level above and below the respective Peltier device 120. In this manner, the desired heat transfer occurs from the ultimate cold sink 180 to the ultimate heat sink 160. It will be understood that although only 4 levels of the multistage thermoelectric cooler are shown in FIG. 18, an arbitrary number of levels n may be built to effect the desired heat transfer necessary for the application. It will also be understood that each multistage thermoelectric cooler may be arranged in an array (as in FIG. 16) to effectively thermoelectrically cool over an array of M×N size.

It will be understood that the choice of Peltier device material between intermediate levels effects the cooling capability. It will be a design choice to select a “good” thermoelectric material as the Peltier device while reducing the number of levels. It will additionally be a design choice to select an inferior Peltier device material while increasing the number of levels to effectively provide the equivalent thermoelectric cooling effect. For simplicity of manufacturing the voltage field (not shown) across each Peltier device 120 is a constant across each stage.

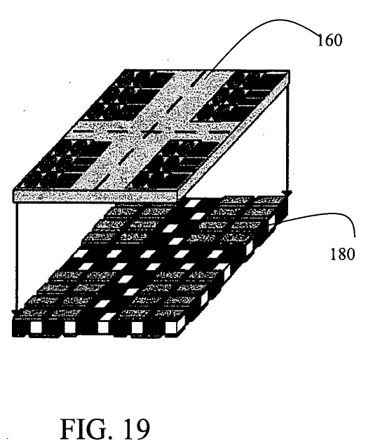

Referring now to FIG. 19, there is shown an isometric schematic diagram of the final M×N thermoelectric array with an ultimate heat sink 160 and an ultimate cold sink 180. The intermediate levels are not shown in the figure. The arrangement of FIG. 19 shows the stacking necessary for effective operation.

While preferred embodiments have been shown and described, various modifications and substitutions may be made thereto without departing from the spirit and scope of the invention. Accordingly, it is to be understood that the present invention has been described by way of illustrations and not limitation.

What is claimed is:

1. A thermoelectric cooler comprising:
a multistage thermoelectric cooler, each stage of said multistage cooler arranged with a Peltier device interposed between an intermediate heat sink and an intermediate cold sink, said Peltier device configured to exhibit a voltage drop.

2. The thermoelectric cooler of claim 1 whereby said multistage thermoelectric cooler effects heat transfer from a cold sink to a hot sink.

3. The thermoelectric cooler of claim 1 wherein said Peltier device is lead telluride.

4. The thermoelectric cooler of claim 1 wherein said Peltier device is bismuth telluride.

5. The thermoelectric cooler of claim 1 wherein said intermediate heat sink of stage n is an intermediate cold sink of stage n-1.

6. The thermoelectric cooler of claim 1 whereby electrons are transferred from said intermediate cold sink to said intermediate hot sink.

7. The thermoelectric cooler of claim 1 wherein said Peltier device is constructed of n-type semiconductor material.

8. The thermoelectric cooler of claim 1 wherein said Peltier device is constructed of p-type semiconductor material.

9. The thermoelectric cooler of claim 1 wherein said cooler is comprised of alternating n-type and p-type semiconductor material at each stage of said multistage thermoelectric cooler.

10. A thermoelectric cooler array comprised of the thermoelectric cooler of claim 1 arranged in an M×N array.

11. The thermoelectric cooler of claim 1 wherein each stage of said multistage thermoelectric cooler is manufactured by slicing a bonded n-type and p-type thermoelectric layer.

12. A method of manufacturing a multistage thermoelectric cooler, said method comprising the steps of:
creating an n-type thermoelectric substrate;
creating a p-type thermoelectric substrate;
selectively bonding said n-type thermoelectric substrate with said p-type thermoelectric substrate horizontally; and
slicing vertically said bonded substrate.

13. The method of claim 12, said method further comprising the step of:
stacking said vertically sliced bonded substrate; and
vertically slicing said stacked bonded substrate in an orthogonal direction to said first vertical slicing step.

14. The method of claim 12 wherein said n-type substrate is lead telluride.

15. The method of claim 12 wherein said p-type substrate is lead telluride.

16. The method of claim 12 wherein said n-type substrate is bismuth telluride.

17. The method of claim 12 wherein said p-type substrate is bismuth telluride.

18. The method of claim 12 wherein said steps are repeated for each specified layer of said multilayer thermoelectric cooler.
